(19) United States
(12) Patent Application Publication
(10) Pub. No.: US 2025/0132198 A1
(43) Pub. Date: Apr. 24, 2025

(54) METHOD OF MANUFACTURING SEMICONDUCTOR DEVICE

(71) Applicant: Samsung Electronics Co., Ltd., Suwon-si, Gyeonggi-do (KR)

(72) Inventors: Yunho KANG, Suwon-si (KR); Minsik KIM, Suwon-si (KR); Yeonuk KIM, Suwon-si (KR); Seran OH, Suwon-si (KR); Byounghoon LEE, Suwon-si (KR); Jangeun LEE, Suwon-si (KR)

(73) Assignee: Samsung Electronics Co., Ltd., Suwon-si, Gyeonggi-do (KR)

(21) Appl. No.: 18/669,981

(22) Filed: May 21, 2024

(30) Foreign Application Priority Data
Oct. 20, 2023 (KR) 10-2023-0140999

(51) Int. Cl. H01L 21/768; H01L 21/3105

(52) U.S. Cl. CPC H01L 21/76831; H01L 21/31058; H01L 21/76814; H01L 21/76816; H01L 21/76825; H01L 21/76877

(57) ABSTRACT

A method of manufacturing a semiconductor device, the method includes forming interconnection lines buried in a first interlayer insulating layer, the interconnection lines having exposed upper surfaces, selectively forming a preliminary low dielectric constant layer including a polymer containing silicon (Si) or an oligomer containing silicon (Si) on an upper surface of the first interlayer insulating layer, forming a low dielectric constant layer by performing ultraviolet (UV) and ozone (O₃) treatments on the preliminary low dielectric constant layer, forming an etch stop layer on the low dielectric constant layer, forming a second interlayer insulating layer on the etch stop layer, and forming a via connected to at least one of the interconnection lines by removing a portion of the second interlayer insulating layer and depositing a conductive material. The via has a shape bent along an upper surface and a side surface of the low dielectric constant layer.

### CROSS-REFERENCE TO RELATED APPLICATION(S)

This application claims benefit of priority under 35 U.S.C. § 119 to Korean Patent Application No. 10-2023-0140999 filed on Oct. 20, 2023 in the Korean Intellectual Property Office, the disclosure of which is incorporated herein by reference in its entirety.

### BACKGROUND

The present inventive concepts relate to methods of manufacturing a semiconductor device.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is required to implement patterns having a fine width or a fine separation distance.

### SUMMARY

Some example embodiments of the present inventive concepts provide a method of manufacturing a semiconductor device having an improved degree of integration and electrical properties.

According to some example embodiments of the present inventive concepts, there is provided a method of manufacturing a semiconductor device, the method including forming interconnection lines buried in a first interlayer insulating layer, the interconnection lines having exposed upper surfaces, selectively forming a preliminary low dielectric constant layer including a polymer containing silicon (Si) or an oligomer containing silicon (Si) on an upper surface of the first interlayer insulating layer, forming a low dielectric constant layer by performing ultraviolet (UV) and ozone (O₃) treatments on the preliminary low dielectric constant layer, forming an etch stop layer on the low dielectric constant layer, forming a second interlayer insulating layer on the etch stop layer, and forming a via connected to at least one of the interconnection lines by removing a portion of the second interlayer insulating layer and depositing a conductive material. The via may have a shape bent along an upper surface and a side surface of the low dielectric constant layer.

According to another example embodiment of the present inventive concepts, there is provided a method of manufacturing a semiconductor device, the method including preparing a substrate structure including a first interlayer insulating layer and interconnection lines buried in the first interlayer insulating layer, the interconnection lines having exposed upper surfaces, selectively forming a preliminary low dielectric constant layer including a polymer containing silicon (Si) or an oligomer containing silicon (Si) on an upper surface of the first interlayer insulating layer, forming a low dielectric constant layer by oxidizing the preliminary low dielectric constant layer, forming a second interlayer insulating layer on the low dielectric constant layer, and forming a via partially passing through the second interlayer insulating layer, the via connected to at least one of the interconnection lines. The via may be in contact with a portion of an upper surface of the low-K layer. The low-K layer may include SiO_{w}CₓF_{y}H_{z}(0<w, 0≤x, 0≤y, 0≤z).

According to another example embodiment of the present inventive concepts, there is provided a method of manufacturing a semiconductor device, the method including preparing a substrate structure including a first interlayer insulating layer and first and second interconnection lines buried in the first interlayer insulating layer, the first and second interconnection lines having exposed upper surfaces, the first and second interconnection lines spaced apart from each other in a horizontal direction, selectively forming a preliminary low dielectric constant layer including a polymer containing silicon (Si) or an oligomer containing silicon (Si) on an upper surface of the first interlayer insulating layer, forming a low dielectric constant layer by performing ultraviolet (UV) and ozone (O₃) treatments on the preliminary low dielectric constant layer, forming a second interlayer insulating layer on the low dielectric constant layer, and forming a via partially passing through the second interlayer insulating layer, the via connected to the second interconnection line. A region of the via, closest to the first interconnection line, may be positioned on a level higher than the upper surface of the first interconnection line.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view illustrating a semiconductor device according to some example embodiments;

FIG. 2 is a cross-sectional view illustrating a semiconductor device according to some example embodiments;

FIGS. 3A to 3C are cross-sectional views illustrating a semiconductor device according to some example embodiments;

FIG. 4 is a cross-sectional view illustrating a semiconductor device according to some example embodiments;

FIG. 5 is a flowchart illustrating a method of manufacturing a semiconductor device according to some example embodiments;

FIGS. 6A to 6G are diagrams illustrating sequential processes of a method of manufacturing a semiconductor device according to some example embodiments;

FIGS. 7A and 7B are diagrams illustrating sequential processes of a method of manufacturing a semiconductor device according to some example embodiments; and

FIG. 8 is a diagram illustrating a method of manufacturing a semiconductor device according to some example embodiments.

### DETAILED DESCRIPTION

Hereinafter, some example embodiments of the present disclosure will be described with reference to the accompanying drawings. Hereinafter, terms such as “top,” “upper portion,” “upper surface,” “above,” “bottom,” “lower portion,” “lower surface,” “below,” and “side surface” may be understood as being referred to based on the drawings except for being denoted by reference numerals.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

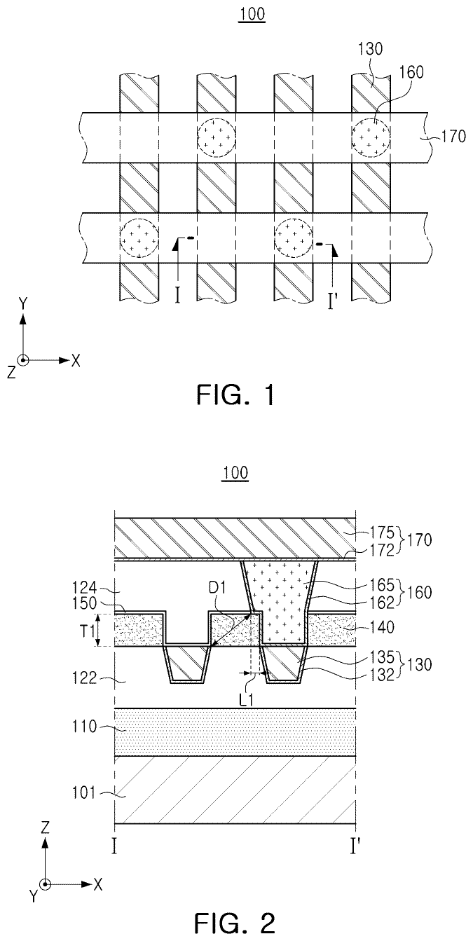

FIG. 1 is a plan view illustrating a semiconductor device according to some example embodiments.

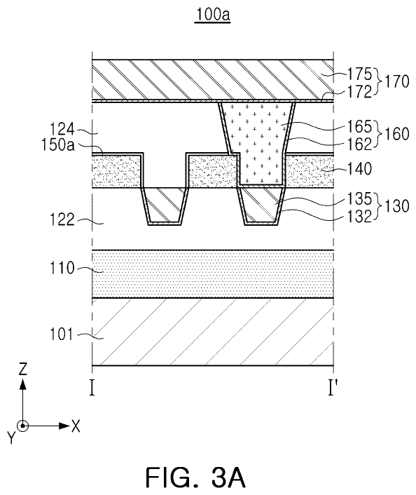

FIG. 2 is a cross-sectional view illustrating a semiconductor device according to some example embodiments. FIG. 2 illustrates a cross-section of the semiconductor device of FIG. 1, taken along line I-I′. For ease of description, FIG. 1 illustrates only some components of the semiconductor device.

Referring to FIGS. 1 and 2, a semiconductor device 100 may include a substrate 101, a device layer 110, a first interlayer insulating layer 122 on the device layer 110, first interconnection lines 130 disposed in the first interlayer insulating layer 122, a low dielectric constant layer 140 on the first interlayer insulating layer 122, an etch stop layer 150 on the low dielectric constant layer, a second interlayer insulating layer 124 on the etch stop layer 150, a via 160 connected to at least one of the first interconnection lines 130, and a second interconnection line 170 connected to the via 160.

The substrate 101 may have an upper surface extending in an X-direction and a Y- direction. The substrate 101 may include a semiconductor material, such as a Group IV semiconductor, a Group III-V compound semiconductor, or a Group II-VI compound semiconductor. For example, the Group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer. In an upper region of the substrate 101, active regions may be defined by, for example, a device isolation layer.

The device layer 110 may be disposed on the substrate 101, and may include semiconductor elements. The device layer 110 may include, for example, at least one of a transistor, a memory cell, an interconnection structure, and/or an insulating layer.

The first interlayer insulating layer 122 may be disposed on the device layer 110, and the second interlayer insulating layer 124 may be disposed on the low dielectric constant layer 140 and the etch stop layer 150. The first and second interlayer insulating layers 122 and 124 may be formed of an insulating material, and may include, for example, at least one of silicon oxide, silicon nitride, and/or silicon oxynitride. In some example embodiments, at least one of the first and second interlayer insulating layers 122 and 124 may include a plurality of insulating layers. In some example embodiments, at least one of the first and second interlayer insulating layers 122 and 124 may include an air gap.

The first interconnection lines 130 may be disposed in the form of being buried in the first interlayer insulating layer 122. Upper surfaces of the first interconnection lines 130 may be exposed through the first interlayer insulating layer 122. The upper surfaces of the first interconnection lines 130 may be coplanar with an upper surface of the first interlayer insulating layer 122. As illustrated in FIG. 1, the first interconnection lines 130 may have a linear shape extending in a direction, for example, Y-direction. The first interconnection lines 130 may be electrically connected to semiconductor elements such as transistors in the device layer 110. The first interconnection lines 130 may be electrically connected to second interconnection lines 170 there above through the via 160. For example, the first interconnection lines 130 may be an n-th interconnection line from the device layer 110, and the second interconnection lines 170 may be an n+1-th interconnection line. A pitch of the first interconnection lines 130, that is, a sum of a width and a separation distance of the first interconnection lines 130, may be in a range of about 10 nm to about 50 nm, for example. The first interconnection lines 130 may have a shape having a decreasing width toward the substrate 101, but the present inventive concepts are not limited thereto, and the first interconnection lines 130 may have a shape having an increasing width toward the substrate 101.

The second interconnection lines 170 may be disposed on the first interconnection lines 130, and may intersect the first interconnection lines 130 and extend in a direction, for example, an X-direction. However, a direction of extension of the second interconnection lines 170 is not limited thereto.

Each of the first interconnection lines 130 may include a first barrier layer 132 and a first conductive layer 135, and each of the second interconnection lines 170 may include a second barrier layer 172 and a second conductive layer 175. The first barrier layer 132 may cover side surfaces and a bottom surface of the first conductive layer 135, and the second barrier layer 172 may cover side surfaces and a bottom surface of the second conductive layer 175. The first and second barrier layers 132 and 172 may prevent or reduce in likelihood the diffusion of materials of the first and second conductive layers 135 and 175. The first and second barrier layers 132 and 172 may include a conductive material, for example, at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boron (NiB). However, in some example embodiments, at least one of the first and second barrier layers 132 and 172 may be omitted. The first and second conductive layers 135 and 175 may include a conductive material, for example, a metal material such as tungsten (W), cobalt (Co), molybdenum (Mo), copper (Cu), ruthenium (Ru), aluminum (Al), or the like.

The low dielectric constant layer 140 may be disposed on the first interlayer insulating layer 122, and may cover only the upper surface of the first interlayer insulating layer 122 such that the first interconnection lines 130 are exposed. In some example embodiments, the low dielectric constant layer 140 may expose only upper surfaces of the first conductive layers 135. The low dielectric constant layer 140 may include a low-κ material, for example, a material having a dielectric constant of 4 or less. The low dielectric constant layer 140 may include a material, different from those of the first and second interlayer insulating layers 122 and 124. For example, the low dielectric constant layer 140 may include at least one of silicon oxide (SiOₓ), silicon carbide oxide (SiOₓC_{y}), silicon hydrogen carbonoxide (SiOₓC_{y}H_{z}), silicon fluorocarbon oxide (SiOₓC_{y}F_{z}), and/or silicon hydrofluorocarbon oxide (SiOₓC_{y}F_{z}H_{w}). Here, x, y, z, and w may be positive real numbers. For example, the low dielectric constant layer 140 may include SiO_{w}CₓF_{y}H_{z}(0<w, 0≤x, 0≤y, 0≤z). In some example embodiments, the low dielectric constant layer 140 may include, in particular, at least one of silicon carbide oxide (SiOₓC_{y}), silicon hydrogen carbonoxide (SiOₓC_{y}H_{z}), silicon fluorocarbon oxide (SiOₓC_{y}F_{z}), and silicon hydrofluorocarbon oxide (SiOₓC_{y}F₂H_{z}). For example, the low dielectric constant layer 140 may include SiO_{w}CₓF_{y}H_{z}(0<w, 0<x, 0≤y, 0≤z).

A first thickness T1 of the low dielectric constant layer 140 may be less than a thickness of each of the first and second interlayer insulating layers 122 and 124. The first thickness T1 may be in a range of, for example, about 1 nm to about 50 nm, for example, from about 10 nm to about 20 nm. When the first thickness T1 is less than the above-described range, a separation distance D1 from an adjacent first interconnection line 130 may not be secured. When the first thickness T1 is greater than the above-described range, a process difficulty level may increase. For example, the first thickness T1 may be equal to or less than a width of the first interconnection line 130, but the present inventive concepts are not limited thereto.

The etch stop layer 150 may extend to cover a portion of upper and side surfaces of the low dielectric constant layer 140 and the upper surfaces of the first interconnection lines 130. The etch stop layer 150 may be interposed between the low dielectric constant layer 140 and the second interlayer insulating layer 124, and may be interposed between the first interconnection lines 130 and the second interlayer insulating layer 124. The etch stop layer 150 may function as an etch stop layer when a via hole for forming the via 160 is formed.

The etch stop layer 150 may include metal oxide, for example, at least one of aluminum oxide, aluminum silicate, titanium oxide, and/or zinc oxide. The etch stop layer 150 may be relatively thin, and may have a thickness of, for example, about 1 Å to about 100 Å, for example, about 3 Å to about 20 Å. However, in some example embodiments, the etch stop layer 150 may be omitted.

The vias 160 may pass through the second interlayer insulating layer 124 and the etch stop layer 150, and may be disposed to vertically connect the first interconnection lines 130 and the second interconnection lines 170 to each other. Arrangements of the vias 160 and the first and second interconnection lines 130 and 170 are not limited to those illustrated in FIG. 1 and may be changed in various manners in some example embodiments.

At least one of the vias 160 may have a region being bent while covering the upper and side surfaces of the low dielectric constant layer 140, as illustrated in FIG. 2. A length L1 of the via 160 in contact with an upper surface of the low dielectric constant layer 140 may be changed in various manners in some example embodiments. The via 160 may have such a bent region, thereby securing the separation distance D1 from the first interconnection line 130, disposed to be adjacent to the via 160 without being connected to the via 160. For example, at least one of the vias 160 may have a region that extends outward in a horizontal direction, for example the X direction as depicted in FIG. 2, toward a first interconnection line 130 that is not connected to the via 160. For example, the distance D1 may be a minimum distance between the via 160 and the interconnection line 130. For example, the distance D1 may correspond to a portion of the via 160 on an upper surface of the low dielectric constant layer 140.

A side end of the via 160 may be a portion where a side surface of the via 160 opposing the adjacent first interconnection line 130 is in contact with the upper surface of the low dielectric constant layer 140. The side end of the via 160 may be a region or point having a smallest horizontal distance between the via 160 and the first interconnection line 130. In some example embodiments, the side end may be a region or point of the via 160 closest to the adjacent first interconnection line 130. Accordingly, the side end of the via 160 may be positioned on a level higher than that of the upper surface of the first interconnection line 130 by the low dielectric constant layer 140, and thus the separation distance D1 may be increased, as compared to a case in which the side end of the via 160 is positioned on a level the same as that of the upper surface of the first interconnection line 130. Even when misalignment occurs when the via 160 is formed, the via 160 may be spaced apart from the adjacent first interconnection line 130 in a vertical direction by the low dielectric constant layer 140, thereby securing the separation distance D1. In FIG. 2, the bent region is illustrated as being formed on a left side surface of the via 160, but a position of the bent region is not limited thereto. In some example embodiments, both side surfaces of the via 160 may have a bent region in cross-sectional view.

Each of the vias 160 may include a via barrier layer 162 and a via conductive layer 165. The via barrier layer 162 may cover side and bottom surfaces of the via conductive layer 165. The via barrier layer 162 may prevent or reduce in likelihood the diffusion of a material of the via conductive layer 165. The via barrier layer 162 may include a conductive material, for example, at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boron (NiB). However, in some example embodiments, the via barrier layer 162 may be omitted. The via conductive layer 165 may include a conductive material, for example, a metal material such as tungsten (W), cobalt (Co), molybdenum (Mo), copper (Cu), ruthenium (Ru), aluminum (Al), or the like.

In the descriptions of the following example embodiments, a description overlapping the above description with reference to FIGS. 1 and 2 will be omitted.

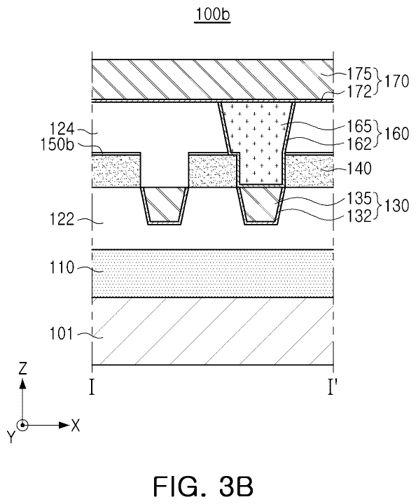

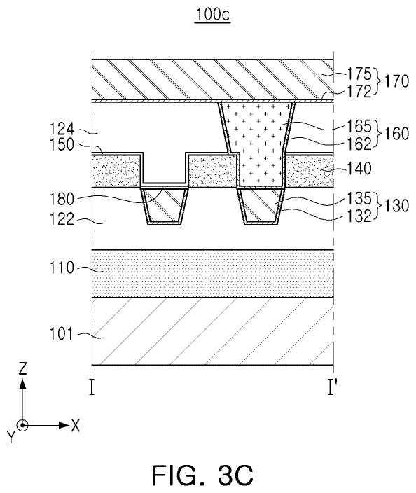

FIGS. 3A to 3C are cross-sectional views illustrating a semiconductor device according to some example embodiments. FIGS. 3A to 3C each illustrate a region corresponding to FIG. 2.

Referring to FIG. 3A, in a semiconductor device 100a, an arrangement of an etch stop layer 150a may be different from that in some example embodiments of FIG. 2. The etch stop layer 150a may be disposed to cover upper and side surfaces of a low dielectric constant layer 140, and may not be disposed on upper surfaces of first interconnection lines 130. The etch stop layer 150a may expose the upper surfaces of the first interconnection lines 130.

Referring to FIG. 3B, in a semiconductor device 100b, an arrangement of an etch stop layer 150b may be different from that in some example embodiments of FIG. 2. The etch stop layer 150b may be disposed to cover an upper surface of a low dielectric constant layer 140, and may not be disposed on side surfaces of the low dielectric constant layer 140 and upper surfaces of first interconnection lines 130. The etch stop layer 150b may expose the side surfaces of the low dielectric constant layer 140 and the upper surfaces of the first interconnection lines 130.

Referring to FIG. 3C, a semiconductor device 100c may further include an oxide layer 180. The oxide layer 180 may be disposed on an upper surface, among upper surfaces of first interconnection lines 130, for example, an upper surface not connected to a via 160. The oxide layer 180 may be disposed between the first interconnection line 130 and the etch stop layer 150. The oxide layer 180 may be a layer formed by partially oxidizing a material of the first interconnection line 130. The oxide layer 180 may include, for example, metal oxide. In a region in which the via 160 is disposed, the via 160 may be disposed to pass through the oxide layer 180, such that the oxide layer 180 may not remain.

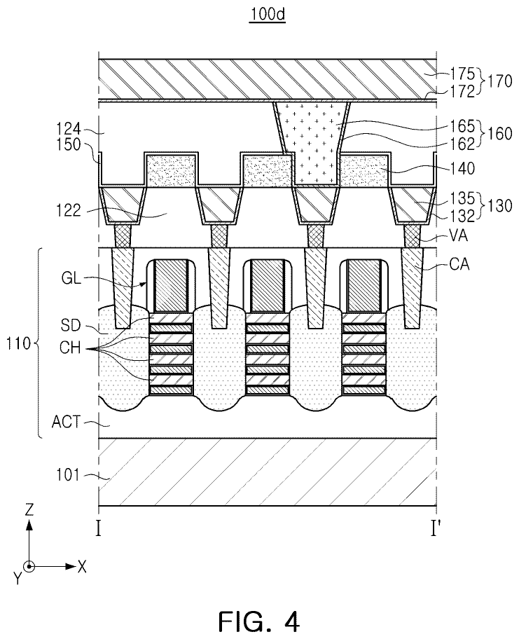

FIG. 4 is a cross-sectional view illustrating a semiconductor device according to some example embodiments. FIG. 4 illustrates a region corresponding to FIG. 2.

Referring to FIG. 4, in a semiconductor device 100d, a device layer 110 may include an active region ACT, a plurality of channel layers CH disposed on the active region ACT to be vertically spaced apart from each other, gate structures GL extending to intersect the active region ACT, the gate structures GL each including a gate electrode, source/drain regions SD in contact with the plurality of channel layers CH, contact plugs CA connected to the source/drain regions SD, and lower vias VA connected to the contact plugs CA.

In the device layer 110, the active region ACT may have a fin structure, and the gate electrode may be arranged to surround the plurality of channel layers CH. Accordingly, the device layer 110 may include transistors having a multi bridge channel FET (MBCFET™) structure, a gate-all-around type field effect transistor.

The active region ACT may be defined by a device isolation layer, and may be disposed to extend in a first direction, for example, an X-direction. The active region ACT may be described as a component included in an upper region of a substrate 101. The active region ACT may be formed as a portion of the substrate 101, or may include an epitaxial layer grown from the substrate 101. In some example embodiments, the active region ACT may include or may not include a well region including impurities.

The gate structures GL may be disposed on the active region ACT and the plurality of channel layers CH to intersect the active region ACT and the plurality of channel layers CH and extend in a second direction, for example, a Y-direction. Functional channel regions of transistors may be formed in the active region ACT and/or the plurality of channel layers CH, intersecting the gate electrodes of the gate structures GL. Each of the gate structures GL may include gate dielectric layers between the gate electrode and the plurality of channel layers CH, and gate spacer layers on side surfaces of the gate electrode. The gate electrode may include a conductive material, and the gate dielectric layers and the gate spacer layers may include a dielectric material.

The plurality of channel layers CH may be disposed on the active region ACT in regions in which the active region ACT intersects the gate structures GL. The plurality of channel layers CH may include two or more channel layers, for example, four channel layers. The plurality of channel layers CH may be connected to the source/drain regions SD. The plurality of channel layers CH may be formed of a semiconductor material.

The source/drain regions SD may be disposed in recessed regions in which an upper portion of the active region ACT is partially recessed on both sides of the gate structure GL. The source/drain regions SD may be disposed to cover side surfaces of each of the plurality of channel layers CH in the X-direction. The source/drain regions SD may include a semiconductor material, and may further include dopants. The source/drain regions SD may be formed of an epitaxial layer.

The contact plugs CA may pass through an insulating layer on the source/drain regions SD, may be connected to the source/drain regions SD, and may apply an electrical signal to the source/drain regions SD. The contact plugs CA may be disposed in the form of the source/drain regions SD being partially recessed, but the present inventive concepts are not limited thereto. The contact plugs CA may include a conductive material. In some example embodiments, each of the contact plugs CA may include a metal silicide layer positioned on a lower portion thereof including a lower surface thereof, and may further include a barrier layer. An interconnection structure, such as a contact plug, may also be further disposed on the gate structures GL.

The lower vias VA may be disposed in a first interlayer insulating layer 122, and may connect the contact plugs CA and first interconnection lines 130. The lower vias VA may include a conductive material. In some example embodiments, interconnection lines and vias may be further disposed between the lower vias VA and the first interconnection lines 130.

As an example of the device layer 110, FIG. 4 illustrates a case in which the device layer 110 includes transistors having an MBCFET™ structure. However, semiconductor elements, disposed on the device layer 110, are not limited thereto.

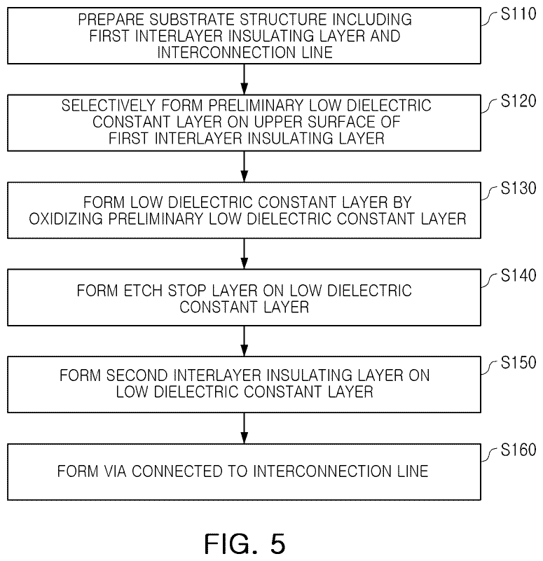

FIG. 5 is a flowchart illustrating a method of manufacturing a semiconductor device according to some example embodiments.

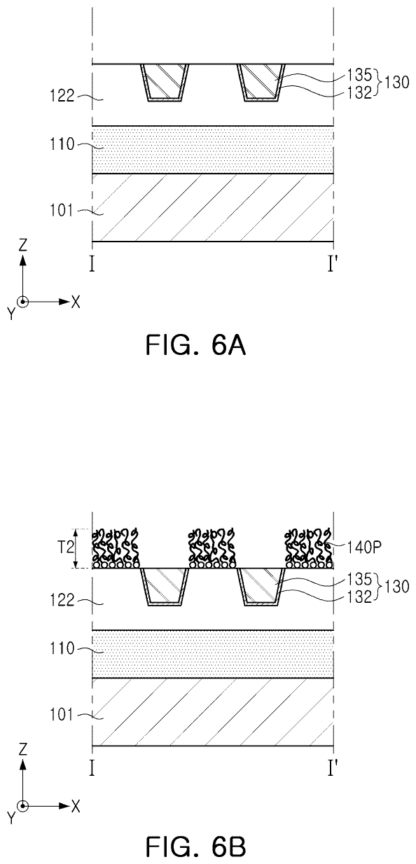

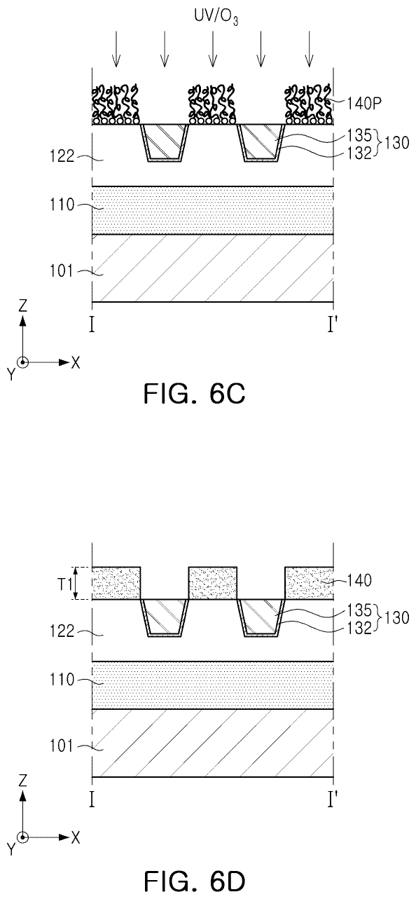

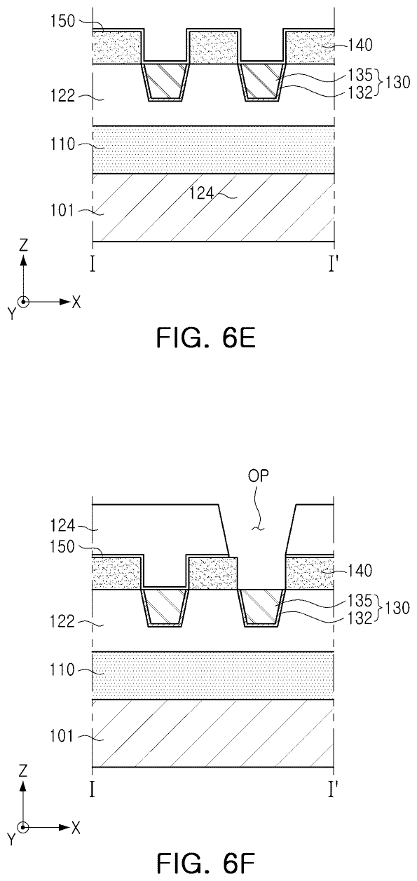

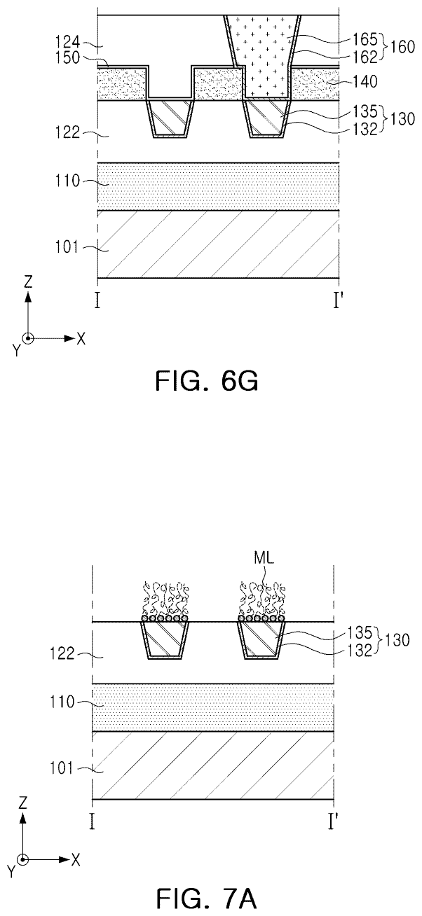

FIGS. 6A to 6G are diagrams illustrating sequential processes of a method of manufacturing a semiconductor device according to some example embodiments. FIGS. 6A to 6G illustrate an example of a method of manufacturing the semiconductor device of FIG. 2.

Referring to FIGS. 5 and 6A, a substrate structure including a first interlayer insulating layer 122 and first interconnection lines 130 may be prepared (S110).

The substrate structure may include a substrate 101 and a device layer 110 on the substrate 101. Depending on example embodiments, the substrate structure may further include interconnection lines on the device layer 110. The first interconnection lines 130 may be formed by partially removing the first interlayer insulating layer 122, depositing a conductive material, and then performing a planarization process such as a chemical mechanical polishing (CMP) process. The first interconnection lines 130 may be formed such that upper surfaces thereof are exposed, and levels of the upper surfaces may be substantially the same. In some example embodiments, the first interconnection lines 130 may be formed by depositing a conductive material on the entire surface of the first interlayer insulating layer 122 and then removing a portion of the deposited conductive material. In this case, the first interlayer insulating layer 122 may be further formed between the first interconnection lines 130.

In some example embodiments, after the first interconnection lines 130 are formed, a cleaning process may be further performed to remove an oxide layer on the upper surfaces of the first interconnection lines 130. The cleaning process may be performed in a reducing atmosphere using hydrogen (H₂), ammonia (NH₃), or the like.

Referring to FIGS. 5 and 6B, a preliminary low dielectric constant layer 140P may be selectively formed on an upper surface of the first interlayer insulating layer 122 (S120).

The preliminary low dielectric constant layer 140P may be formed of a material that may be selectively adsorbed only on the first interlayer insulating layer 122. The preliminary low dielectric constant layer 140P may be a polymer layer containing silicon (Si) or an oligomer layer containing silicon (Si). The polymer or oligomer may be, for example, hydroxyl-terminated polydimethylsiloxane (PDMS-OH). A molecular weight of the polymer or oligomer may be in a range of about 0.1 kg/mol to about 100 kg/mol.

The polymer or oligomer may be formed from a solution state using a method such as spin-coating, dip-coating, drop-casting, or the like, or may be formed using atomic layer deposition (ALD) or chemical vapor deposition (CVD). The preliminary low dielectric constant layer 140P may be formed to have a second thickness T2, which may be selected in consideration of the first thickness T1 of the final low dielectric constant layer 140 of FIG. 6D.

Referring to FIGS. 5, 6C, and 6D, the preliminary low dielectric constant layer 140P may be oxidized to form a low dielectric constant layer 140 (S130).

For the oxidation process, for example, ultraviolet rays (UV) and ozone (O₃) treatments may be performed on the preliminary low dielectric constant layer 140P. A crosslinking reaction of a material, included in the preliminary low dielectric constant layer 140P, may be achieved by the ultraviolet (UV) treatment, and the low dielectric constant layer 140P may be oxidized to remove a portion of carbon (C) and improve stability to moisture and heat by the ozone (O₃) treatment. In some example embodiments, for the oxidation process, at least one of corona discharge, oxygen plasma, and/or oxygen radicals may be used instead of the ultraviolet rays (UV) and ozone (O₃) treatments. The oxidation process may be performed at a temperature of about 20° C. to about 600° C., and ultraviolet ray (UV) and ozone (O₃) treatment time may be in a range of about 1 minute to about 1000 minutes.

The first thickness T1 of the formed low dielectric constant layer 140 may be equal to or less than the second thickness T2 of the preliminary low dielectric constant layer 140P, and may have a proportional relationship with the second thickness T2. Accordingly, the first thickness T1 may be controlled by the second thickness T2, for example, by a molecular weight of a material of the preliminary low dielectric constant layer 140P, for example, a length of one polymer. Alternatively, in some example embodiments, the first thickness T1 may be controlled by repeatedly performing operations S120 and S130 described above. Alternatively, the ultraviolet (UV) and ozone (O₃) treatment time may be increased to relatively reduce the first thickness T1, thereby controlling the first thickness T1.

In some example embodiments, before the ultraviolet (UV) and ozone (O₃) treatments are performed, a solvent or vapor may be applied to the preliminary low dielectric constant layer 140P to cause swelling of the material of the preliminary low dielectric constant layer 140P, thereby adjusting a volume and density of the low dielectric constant layer 140. Accordingly, a dielectric constant may be adjusted.

In some example embodiments, after the low dielectric constant layer 140 is formed, a cleaning process may be further performed to remove the oxide layer on the upper surfaces of the first interconnection lines 130. The cleaning process may be performed in a reducing atmosphere using hydrogen (H₂), ammonia (NH₃), or the like. In some example embodiments, when the cleaning process is not performed before the preliminary low dielectric constant layer 140P is formed and after the low dielectric constant layer 140 is formed, the oxide layer 180 may remain as in the example embodiments of FIG. 3C.

Referring to FIGS. 5 and 6E, an etch stop layer 150 may be formed on the low dielectric constant layer 140 (S140).

The etch stop layer 150 may be conformally formed along the low dielectric constant layer 140 and the upper surfaces of the first interconnection lines 130 using, for example, an ALD process. In some example embodiments, an operation of forming the etch stop layer 150 may be omitted.

In the case of the example embodiments of FIG. 3A, in the present operation, the etch stop layer 150a may be formed by selectively depositing the etch stop layer 150a only on a surface of the low dielectric constant layer 140. In the case of the example embodiments of FIG. 3B, in the present operation, the etch stop layer 150b may be formed by selectively depositing only on a surface of the low dielectric constant layer 140. In this case, a direction in which a deposition material is transferred may be controlled or a gap between the low dielectric constant layers 140 may be used to allow the etch stop layer 150b not to be deposited on side surfaces of the low dielectric constant layer 140.

Referring to FIGS. 5 and 6F, a second interlayer insulating layer 124 may be formed on the low dielectric constant layer 140 and the etch stop layer 150 (S150), and a via hole OP may be formed.

After the second interlayer insulating layer 124 is formed, the via hole OP may be formed passing through the second interlayer insulating layer 124 and exposing a portion of each of the first interconnection lines 130. The via hole OP may be formed to further pass through the etch stop layer 150, and may be formed to expose a portion of an upper surface and side surfaces of the low dielectric constant layer 140. In some example embodiments, a length of the upper surface of the low dielectric constant layer 140, exposed through the via hole OP, may be changed in various manners.

Referring to FIGS. 5 and 6G, a via 160 may be formed by depositing a conductive material in the via hole OP (S160).

The via 160 may be formed to be connected to at least one of the first interconnection lines 130. In at least one region, the via 160 may have a shape bent along the upper surface and the side surfaces of the low dielectric constant layer 140 according to a shape of the via hole OP.

In the present example embodiments, a level between a side end of the via 160 and an upper end of the first interconnection line 130 adjacent thereto may be differently formed by using the low dielectric constant layer 140 selectively formed only on the first interlayer insulating layer 122. Accordingly, a separation distance between the via 160 and the adjacent first interconnection line 130 may be secured using an easy process. For example, as compared to a case in which the low dielectric constant layer 140 is formed of aluminum oxide using ALD, no residue of the low dielectric constant layer may remain on surfaces of the first interconnection lines 130, RC delay may be lowered, and thickness may be easily secured. In addition, as compared to a case in which an upper portion of the first interconnection line 130 is recessed to secure the separation distance, the surface roughness of the first interconnection lines 130 may be prevented or reduced in likelihood from deteriorating.

Next, referring to FIG. 2, a second interconnection line 170 may be formed on the via 160. The second interconnection line 170 may be formed by further forming an interlayer insulating layer on the via 160, partially removing the interlayer insulating layer, and then depositing a conductive material. As a result, the semiconductor device 100 of FIGS. 1 and 2 may be manufactured.

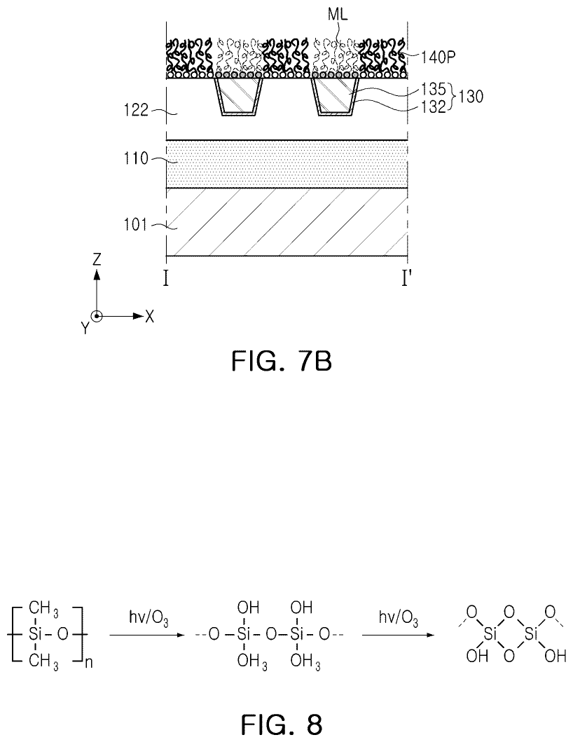

FIGS. 7A and 7B are diagrams illustrating sequential processes of a method of manufacturing a semiconductor device according to some example embodiments. FIGS. 7A and 7B illustrate some operations of some example embodiments of a method of manufacturing the semiconductor device of FIG. 2.

FIGS. 7A and 7B illustrate some example embodiments of operation S120 of selectively forming the preliminary low dielectric constant layer 140P on the upper surface of the first interlayer insulating layer 122, described above with reference to FIG. 6B.

First, as illustrated in FIG. 7A, a mask layer ML may be selectively formed on first interconnection lines 130.

The mask layer ML may include a material that is selectively formed only on metal materials. The mask layer ML may include, for example, a polymer not containing silicon (Si) or an oligomer not containing silicon (Si). The mask layer ML may include, for example, at least one of octadecanethiol (ODT), octadecyl phosphonic acid (ODPA), and/or thiol terminated poly (methyl methacrylate) (PMMA-SH). When the mask layer ML includes ODT or ODPA, the mask layer ML may be formed as a self-assembled monolayer (SAM), but the present inventive concept is not limited thereto. The mask layer ML may include a material that is removed during a process of performing the ultraviolet rays (UV) and ozone (O₃) treatment described above.

Next, as illustrated in FIG. 7B, a preliminary low dielectric constant layer 140P may be formed on an upper surface of a first interlayer insulating layer 122. The preliminary low dielectric constant layer 140P may be formed only on the upper surface of the first interlayer insulating layer 122, exposed from the mask layer ML due to the mask layer ML. The above description with reference to FIG. 6B may be applied to a material of the preliminary low dielectric constant layer 140P and a method of forming the preliminary low dielectric constant layer 140P in the same manner.

Next, the processes described above with reference to FIGS. 6C to 6G may be performed in the same manner, such that the semiconductor device 100 of FIG. 2 may be manufactured. In particular, during the oxidation process of FIG. 6C, the mask layer ML may be converted to the form of carbon monoxide (CO) and/or carbon dioxide (CO₂) and then removed.

FIG. 8 is a diagram illustrating a method of manufacturing a semiconductor device according to some example embodiments.

FIG. 8 illustrates a change in composition of a preliminary low dielectric constant layer 140P during the ultraviolet ray (UV) and ozone (O₃) treatments described above with reference to FIG. 6C with respect to a case in which the preliminary low dielectric constant layer 140P includes PDMS-OH. As treatment time increases, that is, as a degree of oxidation increases, a carbon content may decrease and an oxygen content may increase in a formed low dielectric constant layer 140. For example, as the treatment time increases, the formed low dielectric constant layer 140 may have a composition of SiOₓ, for example, a composition of SiO2 from a composition of SiOₓC_{y}H_{z} or SiOₓC_{y}.

As the treatment time is relatively longer, the formed low dielectric constant layer 140 may have an increasing dielectric constant. Accordingly, the treatment time may be controlled, thereby controlling the composition and dielectric constant of the low dielectric constant layer 140. The dielectric constant of the low dielectric constant layer 140 may also be controlled by a ratio of ultraviolet (UV) irradiation time and ozone (O₃) treatment time.

A preliminary low dielectric constant layer including a polymer or oligomer may be selectively formed in forming a via having a secured vertical distance from an adjacent interconnection line, thereby providing a method of manufacturing a semiconductor device having an improved degree of integration and electrical properties.

While some example embodiments have been shown and described above, it will be apparent to those skilled in the art that modifications and variations could be made without departing from the scope of the present inventive concept as defined by the appended claims.

What is claimed is:

1. A method of manufacturing a semiconductor device, the method comprising:
forming interconnection lines buried in a first interlayer insulating layer, the interconnection lines having exposed upper surfaces;
selectively forming a preliminary low dielectric constant layer including a polymer containing silicon (Si) or an oligomer containing silicon (Si) on an upper surface of the first interlayer insulating layer;
forming a low dielectric constant layer by performing ultraviolet (UV) and ozone (O₃) treatments on the preliminary low dielectric constant layer;
forming an etch stop layer on the low dielectric constant layer;
forming a second interlayer insulating layer on the etch stop layer; and
forming a via connected to at least one of the interconnection lines by removing a portion of the second interlayer insulating layer and depositing a conductive material,
wherein the via has a shape bent along an upper surface and a side surface of the low dielectric constant layer.

2. The method of claim 1, wherein the low dielectric constant layer includes SiO_{w}CₓF_{y}H_{z}(0<w, 0≤x, 0≤y, 0≤z).

3. The method of claim 1, wherein the low dielectric constant layer includes carbon (C).

4. The method of claim 1, further comprising:
forming a mask layer including a polymer not containing silicon (Si) or an oligomer not containing silicon (Si) on the upper surfaces of the interconnection lines, before the preliminary low dielectric constant layer is formed.

5. The method of claim 4, wherein the mask layer is removed during the ultraviolet (UV) and ozone (O₃) treatments.

6. The method of claim 1, wherein a thickness of the low dielectric constant layer is in a range of about 1 nm to about 50 nm.

7. The method of claim 1, wherein the polymer containing silicon (Si) or the oligomer containing silicon (Si) includes hydroxyl-terminated polydimethylsiloxane (PDMS-OH).

8. The method of claim 1, wherein the etch stop layer is formed to expose the upper surfaces of the interconnection lines.

9. The method of claim 8, wherein the etch stop layer further exposes side surfaces of the low dielectric constant layer.

10. The method of claim 1, further comprising:
cleaning the upper surfaces of the interconnection lines in a reducing atmosphere, before the etch stop layer is formed.

11. The method of claim 10, wherein an oxide layer, formed on the upper surfaces of the interconnection lines, is removed by the cleaning.

12. The method of claim 1, wherein levels of the upper surfaces of the interconnection lines are a same level.

13. A method of manufacturing a semiconductor device, the method comprising:
preparing a substrate structure including a first interlayer insulating layer and interconnection lines buried in the first interlayer insulating layer, the interconnection lines having exposed upper surfaces;
selectively forming a preliminary low dielectric constant layer including a polymer containing silicon (Si) or an oligomer containing silicon (Si) on an upper surface of the first interlayer insulating layer;
forming a low dielectric constant layer by oxidizing the preliminary low dielectric constant layer;
forming a second interlayer insulating layer on the low dielectric constant layer; and
forming a via partially passing through the second interlayer insulating layer, the via connected to at least one of the interconnection lines,
wherein the via is in contact with a portion of an upper surface of the low dielectric constant layer, and
the low dielectric constant layer includes SiO_{w}CₓF_{y}H_{z}(0<w, 0≤x, 0≤y, 0≤z).

14. The method of claim 13, wherein the low dielectric constant layer includes SiO_{w}CₓF_{y}H_{z}(0<w, 0<x, 0≤y, 0≤z).

15. The method of claim 13, wherein in the forming the low dielectric constant layer, the preliminary low dielectric constant layer is oxidized using at least one of ultraviolet (UV) and ozone (O₃) treatments, corona discharge, oxygen plasma, or oxygen radicals.

16. The method of claim 13, wherein the via has a bent shape along the upper surface and a side surface of the low dielectric constant layer.

17. The method of claim 13, further comprising:
forming an etch stop layer on the low dielectric constant layer before the second interlayer insulating layer is formed,
wherein the etch stop layer includes metal oxide.

18. A method of manufacturing a semiconductor device, the method comprising:
preparing a substrate structure including a first interlayer insulating layer and first and second interconnection lines buried in the first interlayer insulating layer, the first and second interconnection lines having exposed upper surfaces, the first and second interconnection lines spaced apart from each other in a horizontal direction;
selectively forming a preliminary low dielectric constant layer including a polymer containing silicon (Si) or an oligomer containing silicon (Si) on an upper surface of the first interlayer insulating layer;
forming a low dielectric constant layer by performing ultraviolet (UV) and ozone (O₃) treatments on the preliminary low dielectric constant layer;
forming a second interlayer insulating layer on the low dielectric constant layer; and
forming a via partially passing through the second interlayer insulating layer, the via connected to the second interconnection line,
wherein a region of the via closest to the first interconnection line is positioned on a level higher than the upper surface of the first interconnection line.

19. The method of claim 18, wherein a dielectric constant of the low dielectric constant layer is controlled by ultraviolet (UV) and ozone (O₃) treatment time and/or a ratio of ultraviolet (UV) irradiation time and ozone (O₃) treatment time.

20. The method of claim 18, wherein a thickness of the low dielectric constant layer is controlled by adjusting a molecular weight of the polymer containing silicon (Si) or the oligomer containing silicon (Si).
